(19) United States
(12) Patent Application Publication
(10) Pub. No.: US 2006/0156089 A1
(43) Pub. Date: Jul. 13, 2006

(54) Method and apparatus utilizing defect memories

(76) Inventor: Chao-Yu Yang, Taipei City (TW)

Correspondence Address: BRUCE H. TROXELL;SUITE 1404, 5205 LEESBURG PIKE, FALLS CHURCH, VA, 22041, US

(21) Appl. No.: 11/000,890

(22) Filed: Dec. 2, 2004

(51) Int. Cl. G11C 29/00

(52) U.S. Cl. 714/718

(57) ABSTRACT

A method and apparatus utilizing defect memories is based on damaged section blocks corresponding high bit address division types. A switch set is used to reset an electrical connecting mode between high bit address input end and high bit address output end of the control chip such that high bit address signal sent from the data access system can keep away from damaged section blocks of the defect memories and be transmitted to good section blocks to allow multiple defect memories with different registered section blocks being able to be utilized.

### BACKGROUND OF THE INVENTION

1. Field of the Invention

The present invention is related to a method and apparatus utilizing defect memories and particularly to a method and apparatus with which defect static random access memory (SRAM) or non-volatile memory such as flash memory can be utilized.

2. Brief Description Of Related Art

The memory usually can be divided into two catalogues, volatile memory and non-volatile memory. The volatile memory can provide function of memorization only if the power is on so that the content in the volatile memory disappears while the power is off. The SRAM is belonged to volatile memory and original data therein can be kept if the power supply is not disconnected. The non-volatile memory can keep data therein even if the power is off. Read only memory (ROM) and flash memory are belonged to non-volatile memory.

Taiwanese Patent Official Gazette Publish No. 492,009, entitled “A METHOD OF REARRANGING A SET OF FLASH MEMORIES WITH OUT OF ORDER SECTION THEREOF BEING SYMMETRICAL AND COMPLEMENTARY AND A CIRCUIT THEREOF” discloses a system rearranges data line during data being read to isolate data in the out of order sections and to integrate data in the out of order sections as a complete data for being transmitted out. Further, the out of order flash memories are controlled directly to process various operations during data not being read.

Taiwanese Patent Official Gazette Publish No. 480,495, entitled “METHOD AND DEVICE OF MAKING UP AND UTILIZING DEFECT RANDOM ACCESS MEMORIES” discloses a device used in a computer and the device includes:

a defect memory, which connects with a system address bus of the computer system, a system control signal bus and a system data bus; a special application integrated circuit for making up and utilizing, which connects with the system address bus, the system control signal bus and the system data bus and outputs a control signal to the defect memory; and a non-volatile memory, which is used to store a defect bit address in the defect memory and utilizes a series bus and the integrated circuit for reading data. When the computer system is powered on, the defect bit address is loaded into the integrated circuit. In case of the computer system being ready for accessing actual address, the actual address is compared to the defect bit address. If the comparison fails, the integrated circuit sends the control signal to the defect memory to allow the defect memory performing data access with the system data bus. If the comparison is completed, the integrated circuit sends the control signal to the defect memory to make the defect memory being unable to perform data access with the system data bus.

U.S. Pat. Nos. 6,034,891 and 6,134,143 with the same title, “MULTI-STATE FLASH MEMORY DEFECT MANAGEMENT” disclose a system which arranges data being stored to a certain defect row in the memory to be stored at overhead location of the defect row.

### SUMMARY OF THE INVENTION

The present invention aims to be feasible for different defect types memories being more possible to be utilized and to allow a processing device being capable of variously combining different defect types and different number memories.

An object of the present invention is to provide a method and apparatus utilizing defect memories, which make various damage types registered section blocks being more possible to be utilized.

Another object of the present invention is to provide a method and apparatus utilizing defect memories with which a processing device is capable of variously combining different defect types and different numbers of memories.

A method and apparatus utilizing defect memories is based on damaged section blocks corresponding high bit address division types and utilizes a switch set to reset an electrical connecting mode between high bit address input end and high bit address output end of the control chip such that high bit address signal sent from the data access system can keep away from damaged section blocks of the defect memories and be transmitted to good section blocks to allow multiple defect memories with different registered section blocks being able to be used as a memory with a capacity slightly less than the original or to be associated with a plurality of defect memories, which have various damaged registered section blocks, as a memory with the same capacity or with a capacity multiple times of the original capacity.

### BRIEF DESCRIPTION OF THE DRAWINGS

The present invention can be more fully understood by reference to the following description and accompanying drawings, in which:

FIGS. 1A and 1B are diagrams illustrating a defect memory being divided into eight sections sequentially with three high bit according to the present invention;

FIG. 2 is a structural block diagram of an apparatus utilizing a defect memory according to the present invention being pivotally joined to a frame of the casing;

FIG. 3 is a diagram illustrating two damaged sections in the defect memory according to the present invention;

FIG. 4 is a diagram illustrating two defect memories being utilized according to the present invention;

FIG. 5 is a table of CE00, CEB01 and CEB02 output true values of a control chip according to the present invention;

FIG. 6 is a diagram illustrating a defect memory with a non-defect memory being utilized according to the present invention;

FIG. 7 is a diagram illustrating another embodiment of a defect memory with a non-defect memory being utilized according to the present invention;

FIG. 8 is a diagram illustrating the first embodiment of two defect memories being utilized according to the present invention;

FIG. 9 is a diagram illustrating the second embodiment of two defect memories being utilized according to the present invention;

FIG. 10 a diagram illustrating the third embodiment of two defect memories being utilized according to the present invention;

FIG. 11 is a diagram illustrating the first embodiment of two defect memories with a non-defect memory being utilized according to the present invention;

FIG. 12 is a diagram illustrating the second embodiment of two defect memories with a non-defect memory being utilized according to the present invention;

FIG. 13 is a diagram illustrating an embodiment of a defect memory having less capacity with a plurality of memories having small capacities being utilized according to the present invention; and

FIG. 14 is a flow chart of a method for utilizing defect memories according to the present invention.

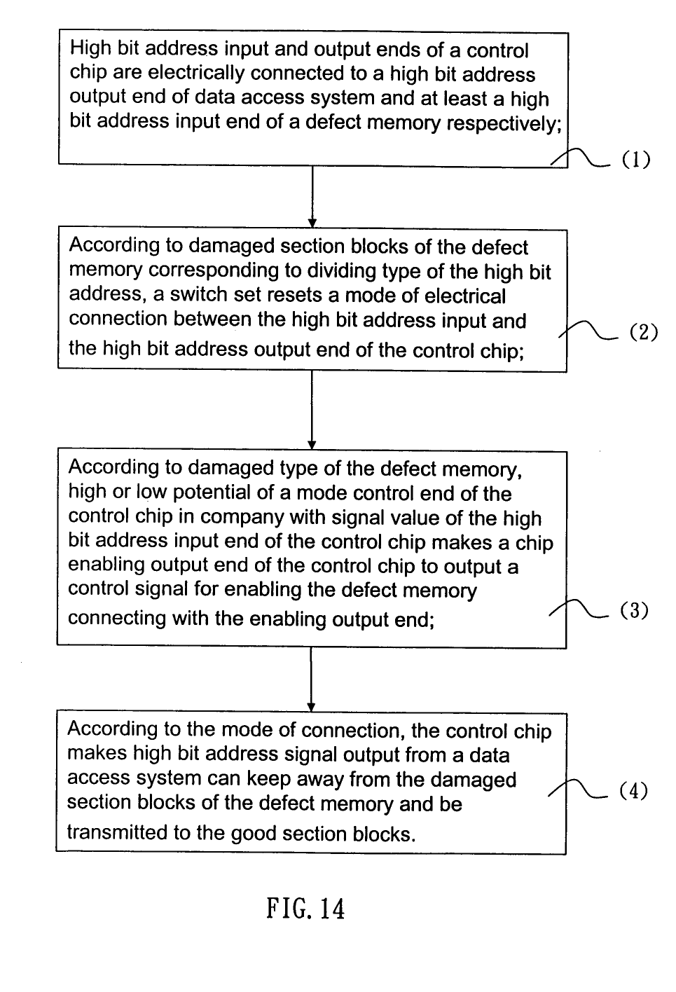

### DETAILED DESCRIPTION OF THE INVENTION

The present includes two aspects that one of the two aspects is optional section blocks being divided in a defect memory with good section blocks being selected randomly and the other aspect is optional section blocks being divided in a defect memory with good section blocks being selected randomly and rearranged. The NOR flash memory is taken as an example and explained hereinafter.

1. Optional section blocks being divided in a defect memory with good section blocks being selected randomly:

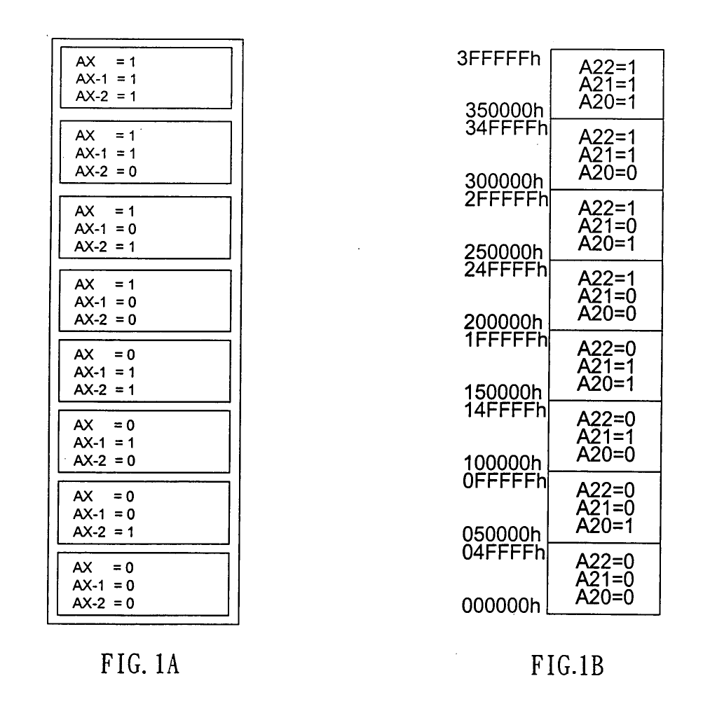

Referring to FIG. 1A, a flash memory card usually has specific addresses therein to identify the accessed section blocks and the flash memory card can be divided based on a feature of different address lines corresponding to a section block respectively. Thus, the accessed section blocks of the memory can be divided by means of sequentially controlling at least a high bit line such that defect section blocks can be differentiated from non-defect section blocks.

Referring to FIG. 1B, the highest bit address A22 has two control states, A22=0 and A22=1. The flash memory can be divided into two parts once the highest bit address line A22 is controlled. By the same token, under the same condition of control states of other low bit address lines (A21˜A0), A22=0 and A22=1 represent the lower half section block and the upper half section block respectively. In case of the control extending to the two-bit address lines A22 and A21 of the highest bit, it is capable of dividing four section blocks. In case of three bit address lines A22, A21 and A20 being sequentially controlled, it is capable of dividing eight section blocks and so on. As for expanding to other memories with capacities different from the preceding one, it can be seen in FIG. 1A that it is supposed that sequence of the highest bit address lines is AX, AX-1 and AX-2. The memory can be divide into 8 section blocks, 000, 001, 010, 100, 101, 110 and 111 because AX and AX-1 each have two control states “0” and “1”. If one of the 8 section blocks is damage section of the defect memory, there are 8 damage types being found. Further, the number of the divided section blocks is expressed as 2^{N} and N represents the number of the controlled high bit address lines. For instance, when two highest bit address lines AX and AX-1 are controlled, the number of the divided section blocks is 2¹=2. When three highest bit address lines AX, AX-1 and AX-2 are controlled, the number of the divided section blocks is 2³=8. Accordingly, When N highest bit address lines are controlled, the number of the divided N section blocks is 2^{N}.

After the memory being divided according to the preceding way and defect section blocks being removed, proportion R of capacity of the defect memory to original capacity thereof can be expressed as:
R=(2^{N}−M)/2^{N} (1)
wherein, M represents number of defect block sections.

For example: If there are three highest bit address lines, the number of the divided section blocks is 2³=8. If there are two defect section blocks, i.e., M=2, the left capacity of the memory proportional to the original capacity can be calculated as
(2³−2)/2³=6/8=3/4

If there are five highest bit address lines, the number of the divided section blocks is 2⁵=32. It is supposed that there are 7 defect section blocks, i.e., M=7 and the left capacity of the memory proportional to the original capacity is (2⁵−7)/2³=25/32

If there are fifteen highest bit address lines, the number of the divided section blocks is 2¹⁵=32768. It is supposed that there are 3500 defect section blocks, i.e., M=3500 and the left capacity of the memory proportional to the original capacity is (2¹⁵−3500)/2¹⁵=29268/32768

The number of various types damaged section blocks in a defect memory can be calculated with the following formula of permutation and combination:
C(2^{N}, M)=2^{N}!/[(2^{N}−M)!*M!] (2)
wherein, 2^{N} represents the number of the divided section blocks and M represents number of defect block sections after dividing.

For example: A defect memory has eight divided section blocks with two damaged section blocks and the number of various types damaged section blocks in the defect memory can be obtained according to formula (2):
C(8,2)=8!/[(8−2)!*2!]=28

Hence, it is known that there are 28 different damage types and the damage typed section blocks have a respective distributed location different from each other. Accordingly, each of the 28 damaged types belongs to a memory with less capacity having two damaged section blocks. The defect memory can be optionally divided into section blocks and the good section blocks can be selected randomly to form a memory with less capacity in use.

2. Optional section blocks being divided in a defect memory with good section blocks being selected randomly and rearranged:

First of all, each defect memory is divided with the preceding way and damaged section blocks are removed to form a memory with less capacity. Then, other memories with small capacities can be combined with the defect memory to make up the damaged section blocks. In this way, the combined memory is still a memory with full capacity or with a capacity multiple times of the original capacity.

The combined memory with small capacity can be at least a good memory with small capacity or at least a memory with less capacity having damaged section blocks. Alternatively, the combined memory can be at least a good memory with small capacity and a memory with less capacity having damaged section blocks. The concept of the combination can be described with the following formula:
(2^{N}−M)/2^{N}+Σ(Mⱼ/2^{N})=1 (3)
(2^{N}−M)/2^{N}+Σ(Mₖ/2^{N})=N (4)
wherein, 2^{N} represents the number of the divided section blocks and M represents number of defect block sections after dividing. Mⱼ and Mₖ represent number of good block sections after dividing. In formula (3), j≧1 and Σ (Mⱼ/2^{N}) represents at least a memory with small capacity with Σ Mⱼ=M. Formula (3) expresses a defect memory combining at least a memory with small capacity to form a memory with full capacity. For example, a defect memory with a capacity of 64M-bits, which is left a capacity of 56M-bits can combine with a defect memory with at least a capacity with 8M-bits or a good memory to form a memory with a capacity of 64M-bits. In formula (4), k≧2, Σ (Mₖ/2^{N}) represents combining at least two memories with two small capacities and Σ Mₖ>M. N is a natural number and N≧2. Formula (4) represents a defect memory combining at least two memories with small capacities and forming memory with a capacity of multiple times of the original capacity. For example, a defect memory with a capacity of 64 M-bits, which has left a capacity of 56M-bits, can combine a memory with a capacity of 50M-bits and at least a memory with a capacity of 22M-bits or a good memory to form two memories with a capacity of 64M-bits respectively or can combine two or more memories with a gross capacity of at least 72M-bits or good memories to form two memories with a capacity of 64M-bits respectively.

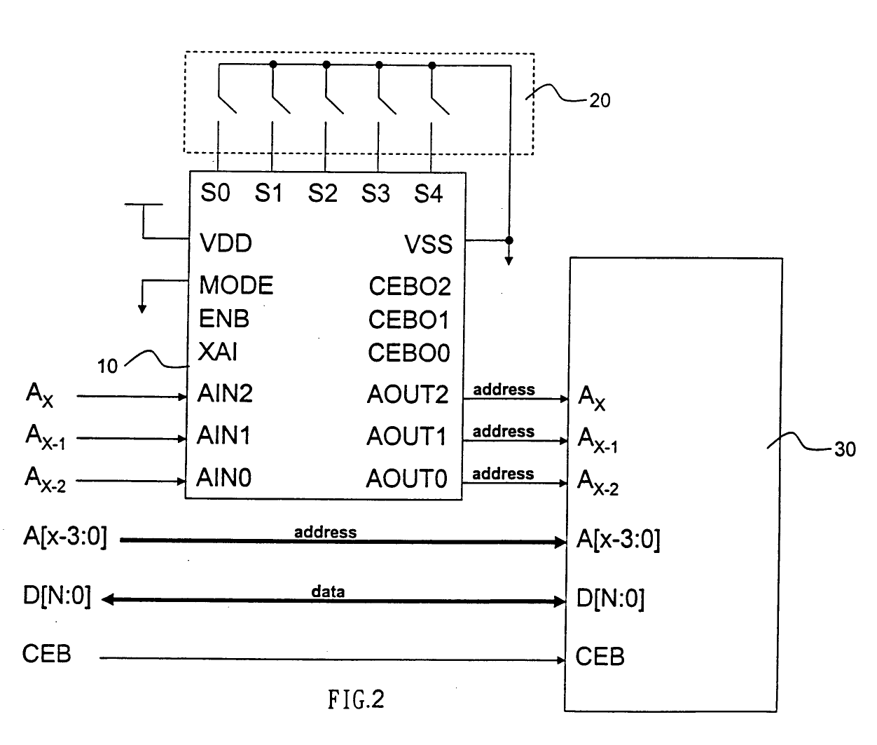

Referring to FIG. 2, a apparatus according to the present invention includes a control chip 10, which has a power source input end VDD, a ground end VSS, a mode control end MODE, input ends XA1, AIN2, AIN1 and AIN0 and output ends AOUT2, AOUT1 and AOUT0 for a plurality of high bit addresses, a chip enabling input end ENB, a plurality of chip enabling output ends CEB00, CEB01 and CEB02 and a plurality of electrical switch connecting ends S0, S1, S2, S3 and S4. The input ends XAI, AIN2, AIN1 and AIN0 are electrically connected to a data access system such as output ends AX, AX-1 and AX-2 of high bit addresses in a computer system. A switch set 20 has a plurality of electrical switches connecting with the electrical switch connecting ends SO, SI, S2, S3 and S4 of the control chip 10. The feature of the present invention is in that the output ends AX, AX-1 and AX-2 of the high bit addresses in a defect memory 30 are electrically connected to the output ends AOUT2, AOUT1 and AOUT0 at the control chip 10 respectively and allows the output ends AX, AX-1 and AX-2 of the high bit addresses in a system to electrically connect with the input ends XA1, AIN2, AIN1 and AIN0 of the high bit addresses at the control chip 10 and further allows an output end A[X-3:0] of a plurality of lower bit addresses and a data transmission output end D[N:0] in the system to electrically connect with input end A[X-3:0] and data input end D[N:0]. Further, it allows the chip enabling output end CEB to electrically connect with the enabling input end CEB of the defect memory 30 or electrically connect with In addition, it results in one of a plurality of chip enabling output ends CEB02, CEB01 and CEB00 at the control chip 10 electrically connects with the enabling input end CEB of the defect memory 30.

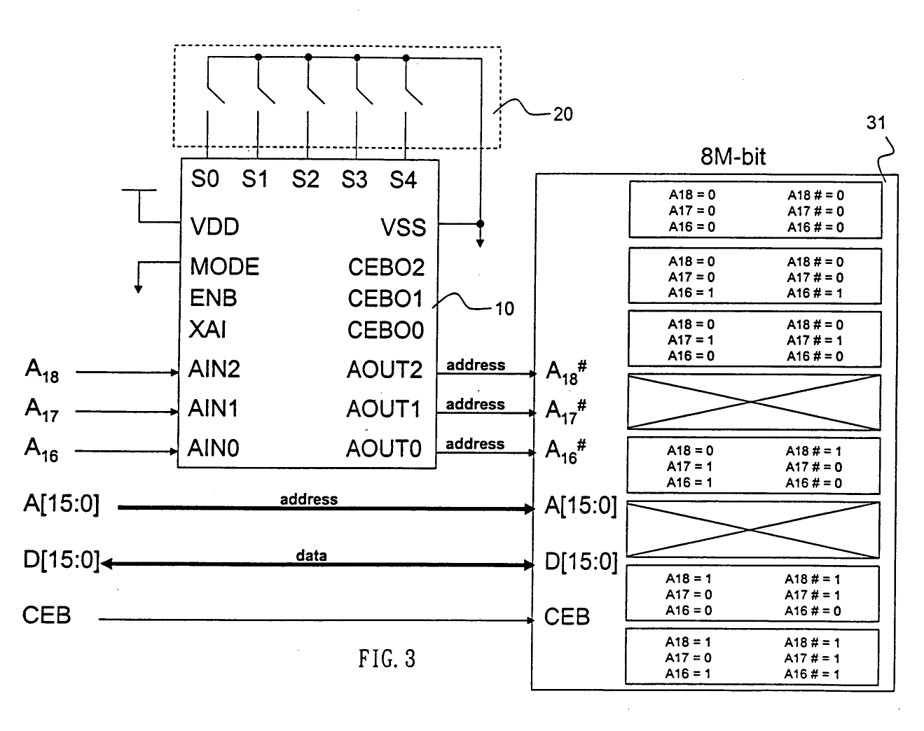

The switch set 20 in the present embodiment has 5 switches and each of the switches has two select modes, “ON” and “OFF” so that the 5 switches have 2⁵, i.e., 32 arrangement modes. When one of the 8 section blocks of the memory shown in FIG. 1A is damaged, there are 8 damage types and when two of the 8 section blocks are damaged, there are 28 damage types. Thus, the control chip 10 can change the connecting route of the system connecting the high bit address of the defect memory 30 such that signal of the high bit address output by the system can keep away from the damaged section blocks and be transmitted to the good section blocks and continuous high bit addresses can be defined in the good section blocks. Therefore, when the defect memory 30 is seen from the system end, the defect memory 30 still has continuously arranged section blocks based on the high bit addresses. For example, when the damaged section blocks of the defect memory 30 is in the section blocks of (A18#=0, A17#=1, A16#=1) and (A18#=1, A17#=0, A16#=1) as shown in FIG. 3, the user can utilize the connecting mode set by the switch set 20 to make the control chip 10 allowing high bit addresses (A18#=0, A17#=1, A16#=1), (A18#=1, A17#=0, A16#=0) and (A18#=1, A17#=0, A16#=1) being defined in the section blocks of (A18#=0, A17#=1, A16#=1), (A18#=1, A17#=0, A16#=0) and (A18#=1, A17#=0, A16#=1) so as to keep away from the 10 preceding damaged section blocks. Hence, the defect memory 31 still can be used as a good memory with a capacity less than the original capacity.

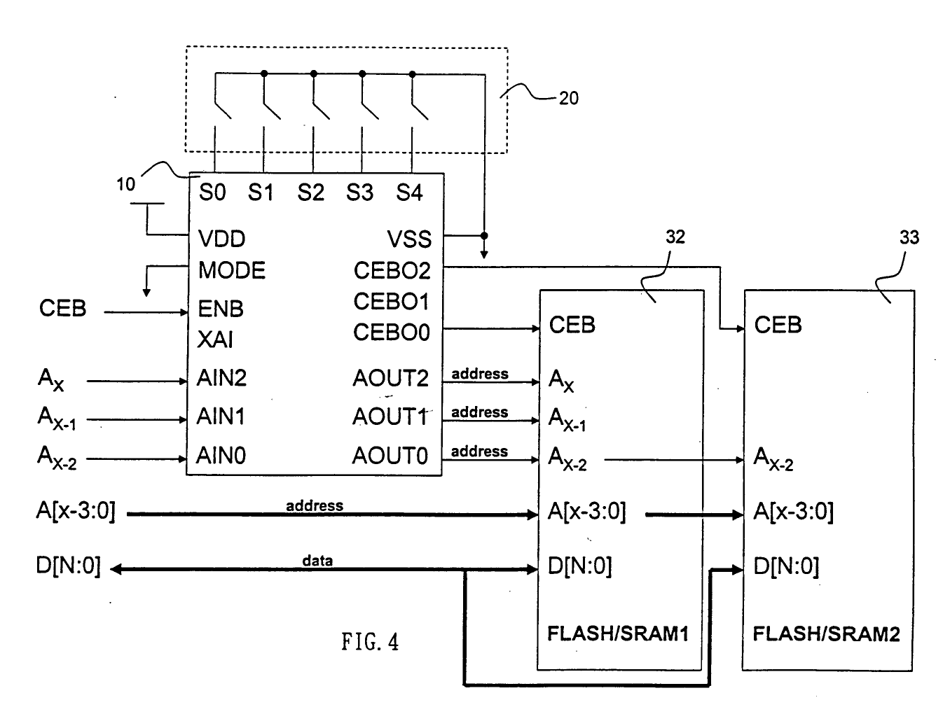

Referring to FIG. 4, the mode control end MODE of the control chip 10 is used for selecting damage type of the defect memory 30. For example, MODE=1 is set in case of a section block being damaged and MODE=0 is set in case of two section blocks being damaged. The electrical connecting end XAI of the highest bit address is used to electrically connect the output end of the high bit address in the system. The user selecting proper connecting mode with the switch set 20 incorporated with high or low value of signal potential received by the chip enabling output end CEB of the system and the input end XAI of the control chip 10 and different combination numerical values of three high bit addresses of the three input ends AIN2, AIN1 and AIN0 of the control chip 10 allows two of the output ends CEB02, CEB01 and CEB00 of the control chip 10 output enabling signals of two defect memories 32, 33 to enable the defect memories 32, 33 such that the system can keep away from the damaged section blocks of the defect memories 32, 33 and it results in the defect memories 32, 33 can be utilized.

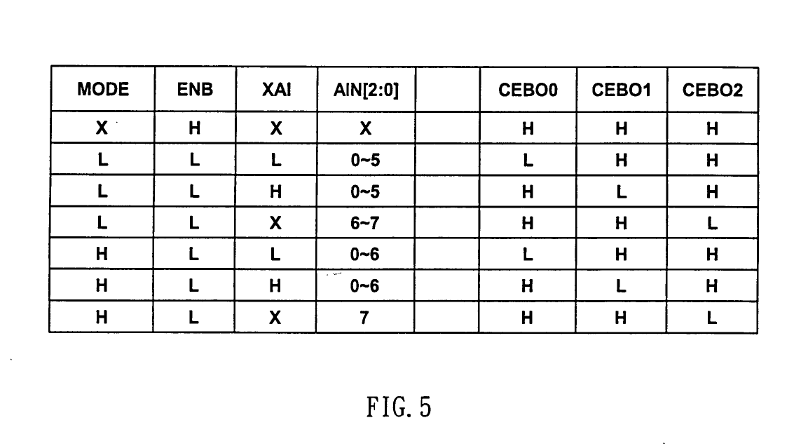

Referring to FIG. 5, ends CE02, CE01 and CE00 enable the defect memories only at low potential (L). Only one of the ends can be at the low potential in at a time. Potentials at the ends CE02, CE01 and CE00 are controlled by the MODE being grounded (L) or connecting high potential (H), ends ENB and XAI being high potential or low potential respectively and magnitude of combination value AIN[2:0] of three continuous ends AIN2, AIN1 and AIN0. “X” in the figure represents the potential can be high potential (H) or low potential (L).

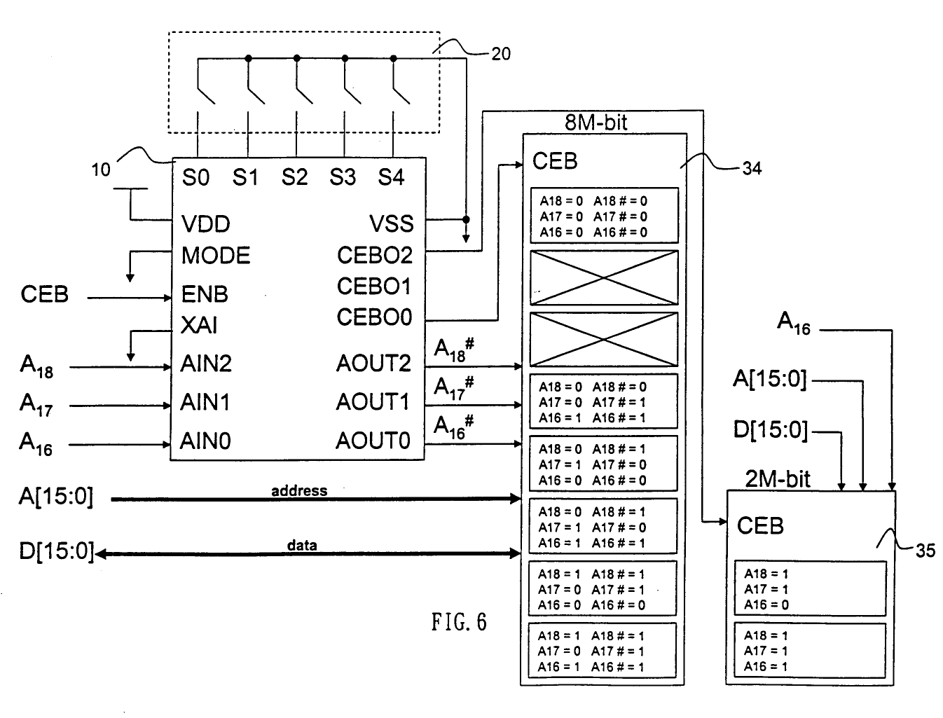

Referring to FIG. 6 in company with FIG. 5, When the user desires ends CEB00 and CEB02 of the control chip 10 to connect with defect memory 34 with a damaged section block and a good memory 35 with less capacity, MODE=0 has to be chosen. Due to the system being not connected to XAI end of the control chip, the XAI end has to be grounded. Further, arrangement mode of the switch 20 is reset based on locations of the damaged section blocks in the defect memory 34 to control connecting modes of both the input end and the output end of the control chip 10 such that the system can keep away from electrically connecting with the damaged section blocks. The present embodiment takes a 8 M-bit defect memory 34 with 2 damaged section blocks associated with a 2M-bit good memory 35 to form an available 8 M-bit memory. The damaged section blocks of the defect memory 34 are (A18#=0, A17#=0, A16#=1) and (A18#=0, A17#=1, A16#=0) and the system can keep away from the preceding damaged section blocks by way of the connecting mode of the control chip 10 being reset by the switch set 20. When the MODE end and XAI end of the control chip 10 is low potential and value of AIN[2:1] is between 0˜5, the defect memory 34 is enabled and the good section blocks are reset as section blocks with continuously arranged high bit addresses and when value of AIN[2:0] is 6 or 7, CEB2 end is low potential to enable the memory 35 and the high bit addresses in registered section blocks of the memory 35 is reset to correspond to subsequent high bit addresses (A18#=0, A17#=0, A16#=1) and (A18#=1, A17#=1, A16#=1) of the defect memory 34.

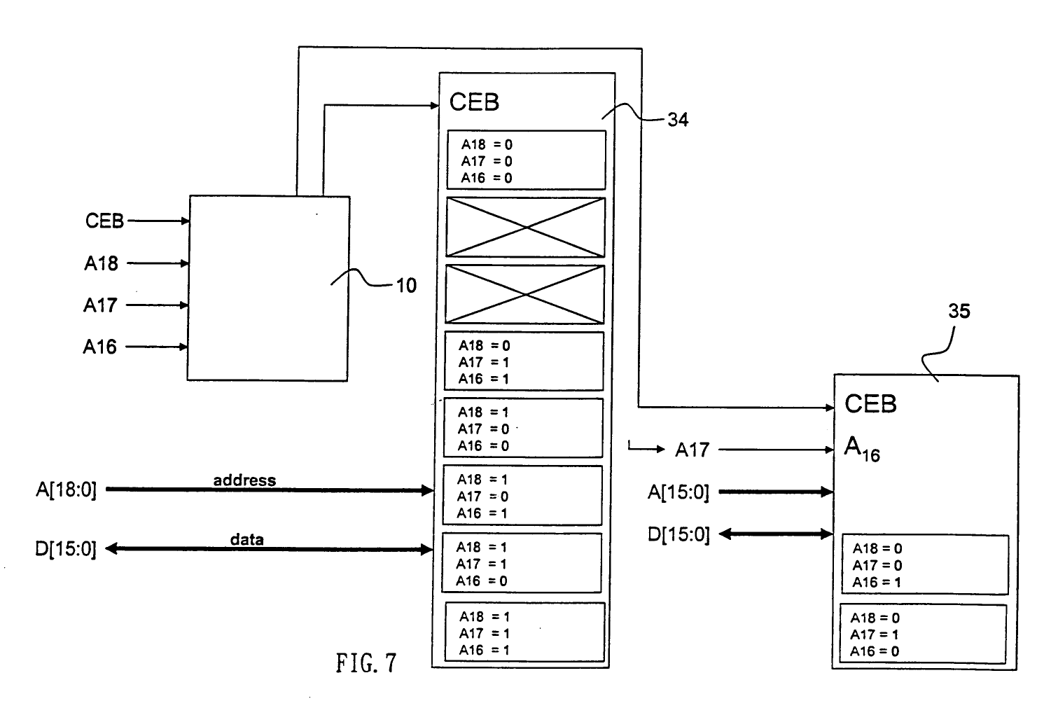

Referring to FIG. 7, the control chip 10 associated with a defect memory 34 and a good memory 35 allows good section blocks of the good memory 35 being reset as (A18#=0, A17#=0, A16#=1) and (A18#=0, A17#=1, A16#=0) instead of damaged section blocks of the defect memory to maintain good section blocks of the defect memory 34 being the original set high bit addresses.

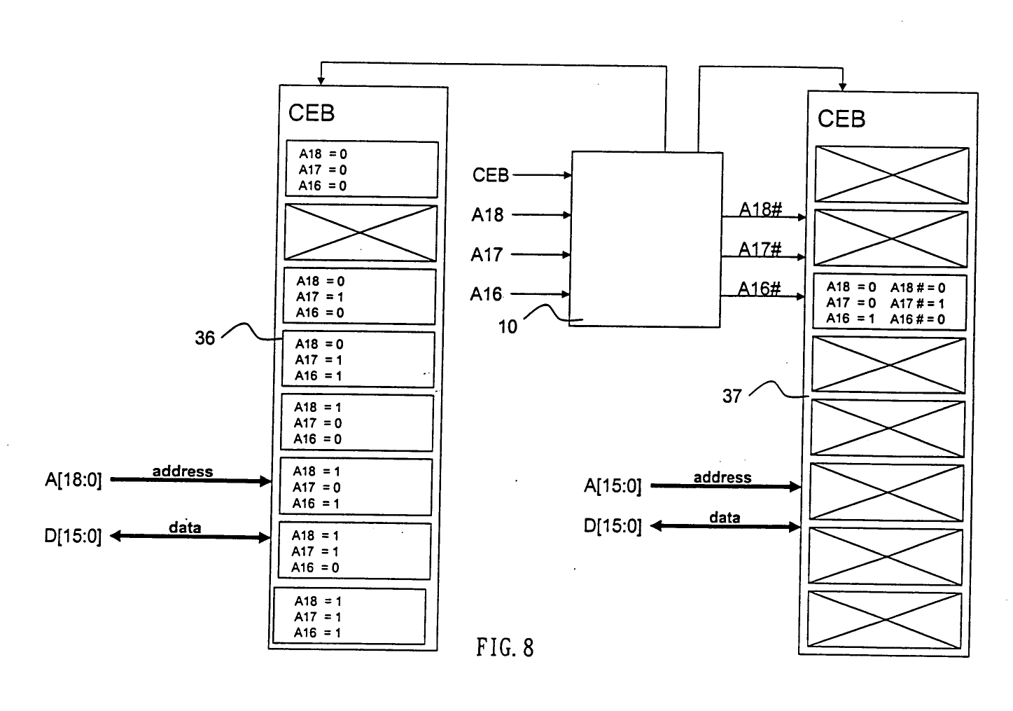

Referring to FIG. 8, the control chip 10 can join with two defect memories 36, 37 with the defect memory 36 having a damaged section block and the defect memory 37 merely having a good section block. The connecting mode of the control chip 10 being reset allows the good section block (A18#=0, A17#=1, A16#=0) of the defect memory 37 replacing the section block (A18#=0, A17#=0, A16#=1) of the defect memory 36 and the two defect memories 37, 36 can be combined as a completely available memory.

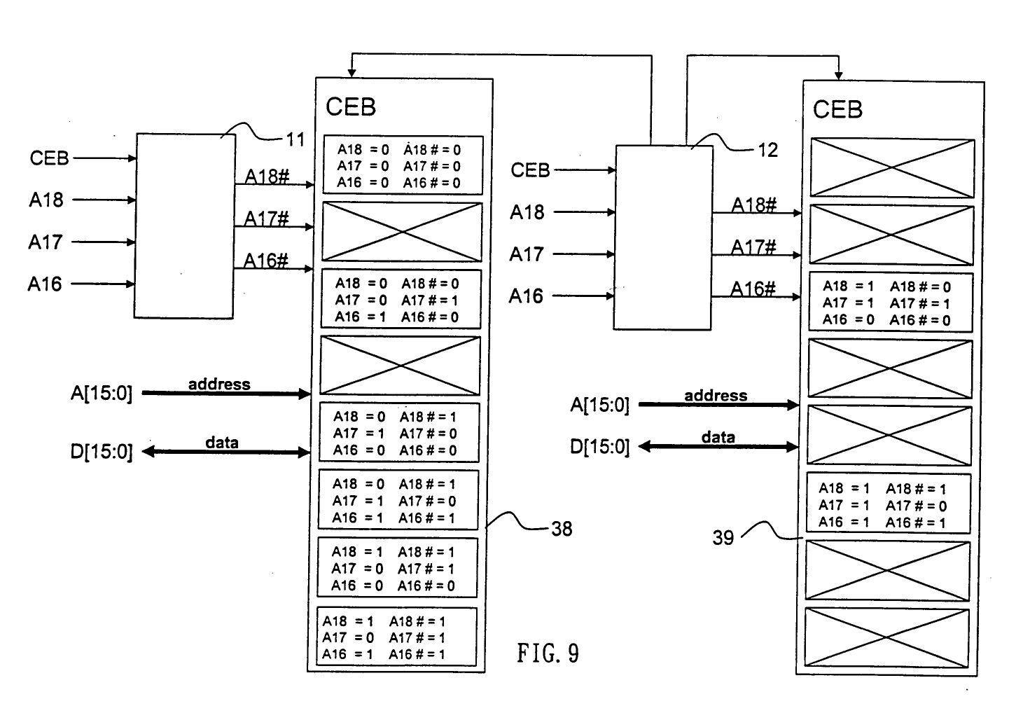

Referring to FIG. 9, two control chips 11, 12 can be adopted to electrically connect with CEB end of the system. Any two of the chip enabling output ends at the control chip 12 are electrically connected to the enabling input ends of two defect memories 38, 39 to control the defect memories 38, 39 being enabled at different time. The two control chips 11, 12 electrically connecting with the defect memories 38, 39 makes the system to keep away from damaged section blocks of the defect memories 38, 39 and to let good section blocks of the memories 38, 39 combining as section blocks with continuous high bit addresses. The control chip 12 in the present embodiment allows two good section blocks corresponding to two damaged section blocks of the defect memory 38. The control chip 12 controlling the defect memories 38, 39 being enabled at different time makes the defect memories 38, 39 to combine a complete memory.

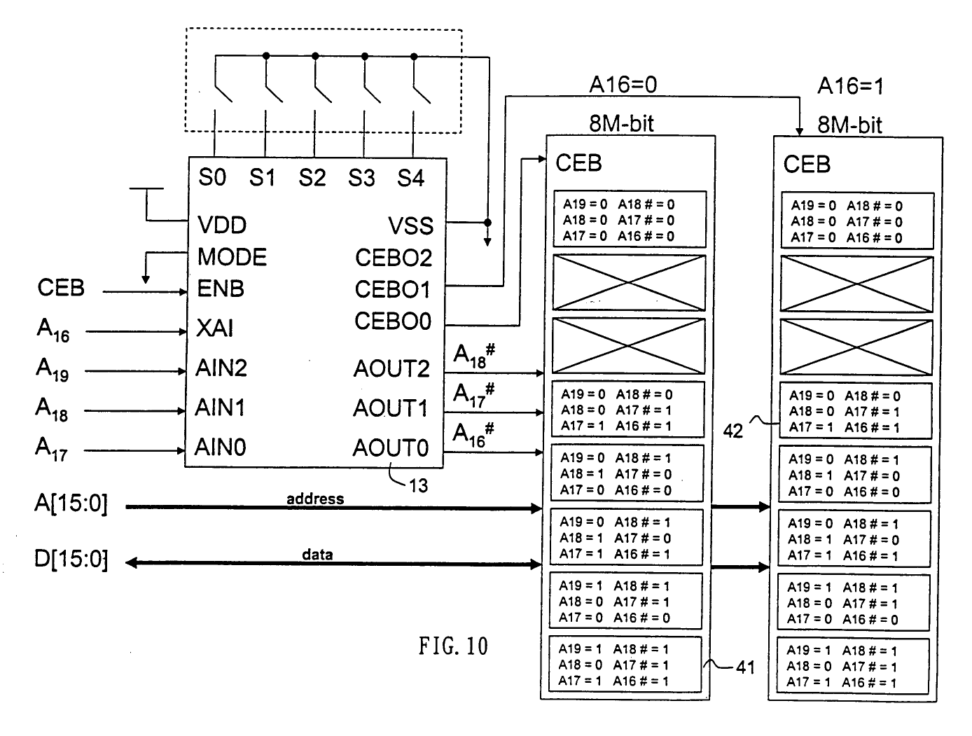

Referring to FIG. 10, another embodiment of the present invention illustrates a control memory 13 connects with two defect memories 41, 42 and the two defect memories 41, 42 have two identical damaged section blocks respectively. High bit address A16 end of the system is electrically connected to an input end (XA1 end) of the highest bit address in the control chip 13. When A16 end is low potential, the control chip 13 enables the defect memory 41 and when A16 end is high potential, the control chip 13 enables the defect memory 42. Thus, good section blocks of the two defect memories 41, 42 can be reset as high bit addresses mutually according to sequence of the good section blocks under control.

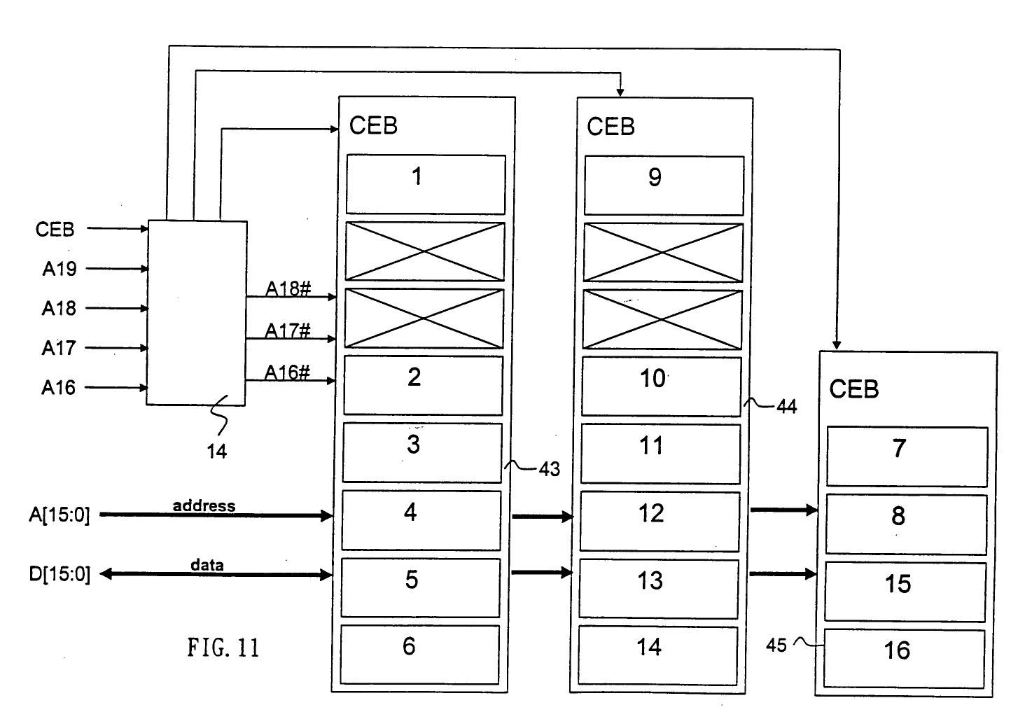

Referring FIG. 11, a further embodiment of the present invention illustrates a control memory 14 is associated with two defect memories 43, 44 and a good memory 45. The two defect memories 43, 44 each have two damaged section blocks respectively and the memory has 4 good section blocks. The control chip 14 makes good section blocks in the memories 43, 44 being reset with successive high bit addresses at 1^{st}˜6^{th} section blocks and at 9^{th}˜14^{th} section blocks respectively and makes high bit addresses of the 4 section blocks in the memory 45 being reset as high bit addresses to supplement 7^{th}˜8^{th} section blocks and 15^{th}˜16^{th} section blocks of the two defect memories such that the two defect memories 43, 44 can combine the memory 45 to form two complete memories with successive high bit addresses respectively.

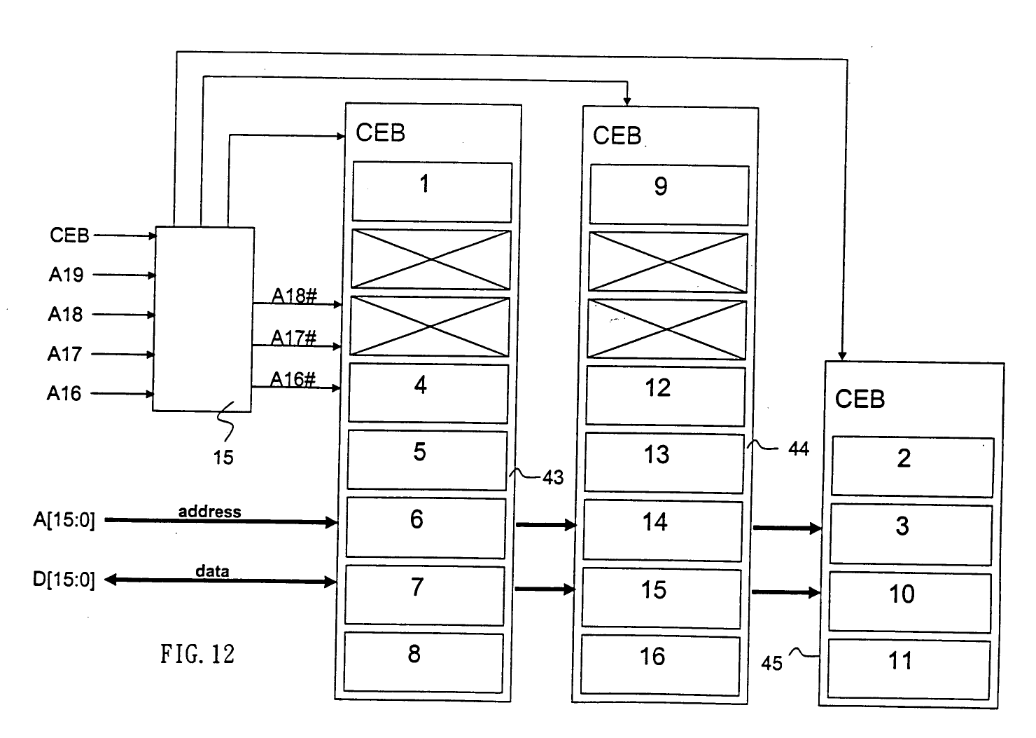

Referring to FIG. 12, a further embodiment of the present invention illustrates a control chip 15 is joined to- the two defect memories 43, 44 respectively and the good memory 45 shown in FIG. 11. The control chip 15 allows the high bit addresses at four section blocks in the good memory 45 being reset high bit addresses of 2˜3 section blocks and 10˜11 section blocks to correspond damaged section blocks of the two defect memories 43, 44 respectively.

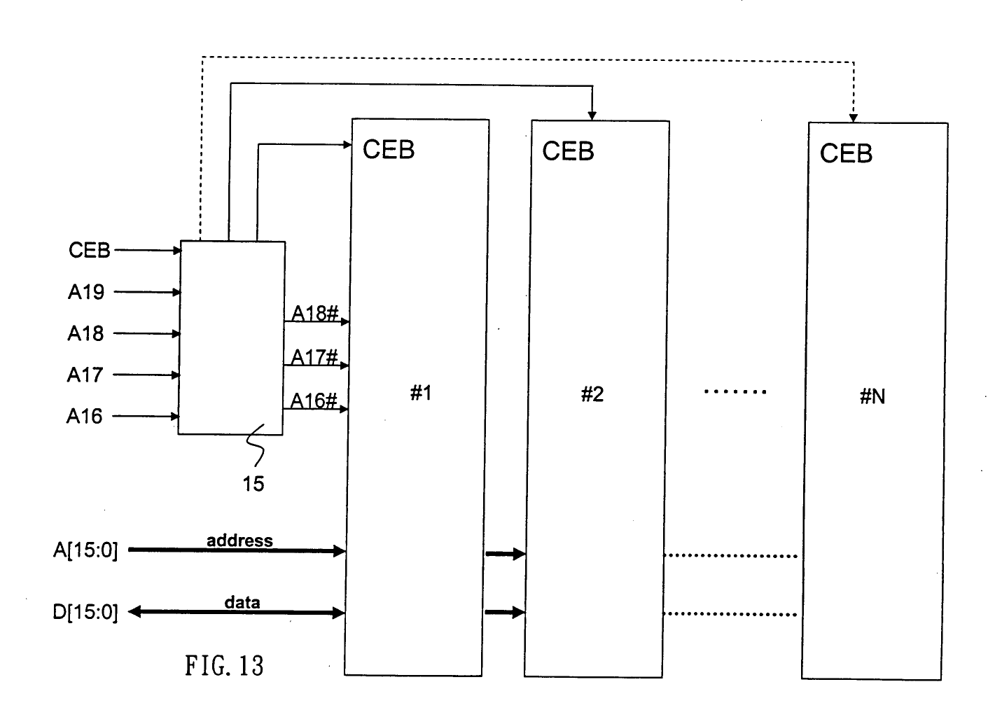

Referring to FIG. 13, a further embodiment of the present invention illustrates the control chip 15 is associated with a defect memory #1 with slightly less capacity and a plurality of memories #2 . . . #N with small capacities such that the memories #1 . . . #N can be combined as a memory with complete capacity or a memory with a capacity multiple times of original capacity.

Referring to 14, the method of the present invention comprises following steps:

(1) High bit address input and output ends of a control chip are electrically connected to a high bit address output end of data access system and at least a high bit address input end of a defect memory respectively;

(2) According to damaged section blocks of the defect memory corresponding to dividing type of the high bit address, a switch set resets a mode of electrical connection between the high bit address input and the high bit address output end of the control chip;

(3) According to damaged type of the defect memory, high or low potential of a mode control end of the control chip in company with signal value of the high bit address input end of the control chip makes a chip enabling output end of the control chip to output a control signal for enabling the defect memory connecting with the enabling output end;

(4) According to the mode of connection, the control chip makes high bit address signal output from a data access system can keep away from the damaged section blocks of the defect memory and be transmitted to the good section blocks.

In case of the control chip connecting with a defect memory only, the step (3) can be omitted and the chip enabling output end of the data access system electrically connects with the enabling input of the defect memory directly to control the defect memory being enabling or disenabling.

The step (3) further comprises the chip enabling output end of the data access end electrically connecting with the enabling input end to control the defect memory being enabled or disenabled.

The invention has following advantages:

1. The registered section blocks of the defect memory are divided into 2ⁿ section blocks and “n” is referred as the number of the divided high bit addresses. The defect memory can have damaged section blocks thereof between 1 to (2ⁿ−1). If a defect memory has the number “A” of the registered section blocks with the number “M” of damaged section blocks, the number of possible damaged type can be calculated with the following formula:
A=2ⁿ,
C(A,M)=A!/[(A−M)!*M!]

When value of n is getting larger, divided registered section blocks are getting smaller so that good section blocks can be distinguished from damaged section blocks precisely and the good section blocks can be fully utilized. The high bit address input and output ends, electrical switch connecting ends and switches of the switch set have to be provided in accordance with the value of n such that that the corresponding electrical connecting mode can be reset to allow defect memories with various damaged types being fully utilized.

2. The present invention further can join multiple defect memories to use good section blocks of the defect memories with same or different damage types instead of using specific number of the defect memories with specific damaged types. The present invention further can join multiple defect memories and one or more good memories such that good section blocks in defect memories with all damaged types can be utilized with the good memories. The preceding formulas can be adopted to describe the concept of combination:
(2^{N}−M)/2^{N}+Σ(Mⱼ/2^{N})=1 (3)
(2^{N}−M)/2^{N}+Σ(Mₖ/2^{N})=N (4)
wherein, 2^{N} represents the number of the divided section blocks and M represents number of defect block sections after dividing. Mⱼ and Mₖ represent number of good block sections after dividing. In formula (3), j≧1 and Σ (Mⱼ/2^{N}) represents at least a memory with small capacity with Σ Mⱼ=M. Formula (3) expresses a defect memory combining at least a memory with small capacity to form a memory with full capacity. For example, a defect memory with a capacity of 64M-bits, which is left a capacity of 56M-bits can combine with a defect memory with at least a capacity with 8M-bits or a good memory to form a memory with a capacity of 64M -bits. In formula (4), k≧2, Σ (Mₖ/2^{N}) represents combining at least two memories with two small capacities and Σ Mₖ>M. N is a natural number and N≧2.

The number of the mode control end and chip enabling output end have to be in accordance with the number of the associated memories in order to enable and utilize the memories respectively.

3. The present invention provides a processing device to join different numbers of defect memories with different damaged types to form an available memory with a capacity smaller than, the same as or greater than the original capacity of a defect memory. Thus, the processing device can be applied widely.

While the invention has been described with referencing to preferred embodiments thereof, it is to be understood that modifications or variations may be easily made without departing from the spirit of this invention, which is defined by the appended claims.

What is claimed is:

1. A method of utilizing defect memory, comprising:
(1) at least a high bit address input end of a control chip being electrically connected to at least a high bit address output end of a data access system and at least a high bit address output end of the control chip being electrically connected to at least a high bit address input end of at least a defect memory respectively;
(2) a switch set being utilized to reset a mode of electrical connection between the high bit address input end and the high bit address output end of the control chip according to damaged section blocks of the defect memory corresponding to divided type of at least a high bit address; and
(3) the control chip controlling a high bit address signal output from a data access system to keep away from the damaged section blocks of the defect memory and be transmitted to the good section blocks according to the mode of electrical connection.

2. The method as defined in claim 1, wherein the control chip in the step (1) electrically connects with a defect memory and has an 20 enabling input end of the defect memory being electrically connected to an enabling output end of the data access system.

3. The method as defined in claim 1, wherein the control chip in the step (1) electrically connects with at least two defect memories and an enabling input end of the control chip electrically connects with an enabling output end of the data access system and an enabling input end at each of the defect memories electrically connects with a corresponding chip enabling output end respectively and a further step, which is between the step (2) and the step (3), is that according to damaged type of each of the defect memories, high or low potential of a mode control end of the control chip in company with signal value of the high bit address input end of the control chip, the chip enabling output end outputs a control signal to enable one of the defect memories.

4. The method as defined in claim 1, wherein the control chip in the step (1) has at least a high bit address output end electrically connecting with at least a high bit address input end of at least a good memory and the enabling input end of the control chip electrically connects with the chip enabling output end of the data access system and the good memory and each of the defect memories at enabling input ends thereof being electrically connected to a corresponding chip enabling output end respectively and a further step, which is between the step (2) and the step (3), is that according to damaged type of each of the defect memories, high or low potential of a mode control end of the control chip in company with signal value of the high bit address input end of the control chip, the chip enabling output end outputs a control signal to enable one of the good memory and the defect memories respectively.

5. The method as defined in claim 1, wherein registered section blocks of the defect memory is divided into 8 section blocks corresponding to three high bit addresses and switch set has 5 switches.

6. The method as defined in claim 3, wherein the step (1) further has the control chip electrically connecting with two defect memories and a high bit address output of the data access system electrically connects with the highest address input end of the control chip such that one of the defect memories can be enabled in case of the highest bit address input end being low potential and another one of the defect memories can be enabled in case of the highest bit address input end being high potential with the good section blocks of the defect memories being set high bit addresses mutually according to sequence of the high bit addresses.

7. The method as defined in claim 4, wherein the step (1) has the control chip electrically connecting with at least a defect memory and a good memory and has good section blocks in the defect memory are reset as continuous arranged section blocks with high bit addresses and high bit addresses of the good memory are reset to correspond to high bit addresses of subsequent section blocks of the defect memory.

8. The method as defined in claim 4, wherein the step (1) has the control chip electrically connecting with at least a defect memory and a good memory and high bit addresses of section blocks in the good memory are reset to correspond to high bit addresses of damaged section blocks in the defect memory.

9. The method utilizing defect memories as defined in claim 5, wherein damaged type of each of the defect memories includes one of 1˜8 damaged section blocks.

10. A method utilizing defect memories, comprising:
(1) at least a high bit address input end of two control chips being electrically connected to at least a high bit address output end of a data access system and at least a high bit address output end of the control chips being electrically connected to at least a high bit address input end of a defect memory respectively and enabling input ends of the control chips electrically connect with an enabling output end of the data access system and enabling input ends at the two defect memories electrically connect with a corresponding chip enabling output end of the first control chip respectively;
(2) two switch sets being utilized to reset a mode of electrical connection between the high bit address input end and the high bit address output end of the control chip according to damaged section blocks of the two defect memories corresponding to divided type of at least a high bit address;
(3) according to damaged types of the two defect memories, high or low potential of a mode control end of the first control chip in company with signal value of the high bit address input end of-the first control chip, the chip enabling output end of the first control chip outputs a control signal to enable one of the two defect memories.
(4) the two control chips controlling a high bit address signal output from a data access system to keep away from the damaged section blocks of the defect memory and be transmitted to the good section blocks according to the mode of electrical connection.

11. An apparatus utilizing defect memories, which is used to join a data access system and memories for removing damaged section blocks of the memories so as to become available memories, comprising:
a control chip, having at least a high bit address input end and at least a high bit address output end, the high bit address input end electrically connecting with at least a high bit address output end od the data access system, the high bit address output end electrically connecting with at least a high bit input end of at least a defect memory;
a switch set, having a plurality of switches electrically connecting with switch connecting ends of the control chip respectively;
whereby, the switch set is utilized to reset a mode of electrical connection between the high bit address input end and the high bit address output end of the control chip according to damaged section blocks of the defect memory corresponding to divided type of at least a high bit address such that high bit address signal output from a data access system can keep away from the damaged section blocks of the defect memory and is transmitted to the good section blocks.

12. The apparatus as defined in claim 11, wherein the control chip electrically connects with a defect memory and an enabling input end of the defect memory electrically connects with a chip enabling output end of the data access system.

13. The apparatus as defined in claim 11, wherein the control chip electrically connects with at least two defect memories and an enabling input end of the control chip electrically connects with a chip enabling output end of the data access system and an enabling input end of each of the defect memories electrically connects with a corresponding chip enabling output end respectively;
whereby, according to damaged type of each of the defect memories, high or low potential of a mode control end of the control chip in company with signal value of the high bit address input end of the control chip, the chip enabling output end outputs a control signal to enable one of the defect memories.

14. The apparatus as defined in claim 11, wherein the control chip has at least a high bit address output end electrically connecting with at least a high bit address input end of at least a good memory and the enabling input end of the control chip electrically connects with the chip enabling output end of the data access system and the good memory and each of the defect memories at enabling input ends thereof being electrically connected to a corresponding chip enabling output end respectively;
whereby, according to damaged type of each of the defect memories, high or low potential of a mode control end of the control chip in company with signal value of the high bit address input end of the control chip, the chip enabling output end outputs a control signal to enable one of the good memory and the defect memories respectively.

15. The apparatus as defined in claim 11, wherein damaged section blocks of the defect memory is divided into 8 section blocks corresponding to three high bit addresses and switch set has 5 switches.

16. The apparatus as defined in claim 11, wherein the control chip electrically connects with a defect memory and further includes:
a second control chip, providing at least a high bit address input end and a high bit address output end, the high bit address input end electrical connecting with at least a high bit output end of the data access system and the high bit address output end electrically connecting with at least a high bit address input end of a second defect memory;
a second switch set, providing a plurality of switches electrically connecting with switch connecting ends of the second control chip so that according to damaged section blocks of the second defect memory corresponding to at least a high bit address division type, the second switch set resets connecting mode between the high bit address input end and the high bit address output end of the second control chip makes high bit address signal sent out of the data access system keeping away from damaged section blocks of the second defect memory and being transmitted to good section blocks;
wherein, enabling input ends of the two control chips electrically connect with the enabling output end of the data access system and enabling input ends of the two defect memories electrically connect with corresponding chip enabling output ends of the control chip respectively;
whereby, according to damaged type of the two defect memories, high or low potential of a mode control end of the control chip in company with signal value of the high bit address input end of the control chip, the chip enabling output ends output a control signal to enable one of the two defect memories.

17. The apparatus as defined in claim 13, wherein the control chip electrically connecting with two defect memories and a high bit address output of the data access system electrically connects with the highest address input end of the control chip such that one of the defect memories can be enabled in case of the highest bit address input end being low potential and another one of the defect memories can be enabled in case of the highest bit address input end being high potential with the good section blocks of the defect memories being set high bit addresses mutually according to sequence of the high bit addresses.

18. The apparatus as defined in claim 14, wherein the control chip electrically connects with at least a defect memory and a good memory and good section blocks in the defect memory are reset as continuous arranged section blocks with high bit addresses and high bit addresses of the good memory are reset to correspond to high bit addresses of subsequent section blocks of the defect memory.

19. The apparatus as defined in claim 14, wherein the control chip electrically connects with at least a defect memory and a good memory and high bit addresses of section blocks in the good memory are reset to correspond to high bit addresses of damaged section blocks in the defect memory.

20. The apparatus as defined in claim 14, wherein the control chip electrically connects with a defect memory and a good memory.

21. The apparatus as defined in claim 14, wherein the control chip electrically connects with two defect memories and a good memory.

22. The apparatus as defined in claim 15, wherein damaged type of each of the defect memories includes one of 1˜8 damaged section blocks.
